(19) United States
(12) Patent Application Publication
(10) Pub. No.: US 2026/0047248 A1
(43) Pub. Date: Feb. 12, 2026

(54) TEST STRUCTURES FOR SEMICONDUCTOR WAFERS

(71) Applicant: Taiwan Semiconductor Manufacturing Company, Ltd., Hsinchu (TW)

(72) Inventors: Jheng-Hong Jiang, Hsinchu (TW); Shing-Huang Wu, Hsinchu (TW)

(21) Appl. No.: 18/798,384

(22) Filed: Aug. 8, 2024

(51) Int. Cl. H01L 33/62; H01L 21/66; H01L 25/075; H01L 33/58

(52) U.S. Cl. CPC H10H 20/857; H01L 22/32; H01L 25/0753; H10H 20/855; H10H 20/0363; H10H 20/0364

(57) ABSTRACT

A testing structure for a semiconductor wafer substrate is formed from a trench and a via connected to the perimeter of the trench. The via also connects to an interconnection. The via is filled with a first electrically conductive material, and the trench also includes a second electrically conductive material that is more stable than the first electrically conductive material. A conductive path extending vertically from the interconnection to an upper surface of the testing structure passes through only the first electrically conductive material. The use of the second electrically conductive material reduces or prevents migration of atoms/ions within the first electrically conductive material and so increases system reliability.

### BACKGROUND

Integrated circuits are formed on a semiconductor wafer. Photolithographic patterning processes use ultraviolet light to transfer a desired mask pattern to a photoresist on a semiconductor wafer. Etching processes may then be used to transfer to the pattern to a layer below the photoresist. This process is repeated multiple times with different patterns to build different layers on the wafer substrate and make a useful device. Due to small critical dimensions, testing of the completed structures is performed to ensure they function as desired.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a plan view of a semiconductor system, in accordance with some embodiments of the present disclosure. FIG. 1B is a Y-axis cross-sectional view through line B-B of FIG. 1A. These views show one chip area and one testkey area.

FIG. 1C is a plan view of another semiconductor system. This view shows one testkey area which is electrically connected to four chip areas.

FIG. 2 is a flow chart illustrating a first method for making a testing structure for a semiconductor system, in accordance with some embodiments.

FIG. 3 is a Y-axis cross-sectional view of the semiconductor system after patterning of a first mask layer upon a dielectric layer.

FIG. 4 is a Y-axis cross-sectional view of the semiconductor system after formation of vias.

FIG. 5 is a Y-axis cross-sectional view of the semiconductor system after patterning of a second mask layer.

FIG. 6A is a plan view of the semiconductor system after formation of trenches over the vias. FIG. 6B is a Y-axis cross-sectional view of the semiconductor system.

FIG. 7 is a Y-axis cross-sectional view of the semiconductor system after deposition of a first barrier layer upon exposed surfaces of the vias and trenches.

FIG. 8 is a Y-axis cross-sectional view of the semiconductor system after deposition of a first electrically conductive material. This material fills the vias.

FIG. 9 is a Y-axis cross-sectional view of the semiconductor system after deposition of a second electrically conductive material.

FIG. 10 is a Y-axis cross-sectional view of the semiconductor system after planarization to remove excess electrically conductive material. The testing structure may be considered complete after this step, if desired.

FIG. 11 is a Y-axis cross-sectional view of the semiconductor system after deposition of a first dielectric layer.

FIG. 12 is a Y-axis cross-sectional view of the semiconductor system after patterning of a third mask layer.

FIG. 13 is a Y-axis cross-sectional view of the semiconductor system after formation of first sidewall(s) above and around the device structure(s) and the testing structure.

FIG. 14A is a view illustrating how the various layers of the testing structure correspond to each other from a Y-axis cross-sectional to a plan view, in one embodiment of the testing structure.

FIG. 14B is a plan view of a second embodiment of the testing structure. Here, the testing structure has a rectangular shape, with the via having a rectangular shape in a different corner.

FIG. 14C is a plan view of a third embodiment of the testing structure. Here, the testing structure has a rectangular shape, with the via having a different rectangular shape.

FIG. 14D is a plan view of a fourth embodiment of the testing structure. Here, the testing structure is in the shape of a cross.

FIG. 14E is a plan view of a fifth embodiment of the testing structure. Here, the testing structure is in the shape of a parallelogram.

FIG. 14F is a plan view of a sixth embodiment of the testing structure. Here, the testing structure is in the shape of a triangle.

FIG. 15 is a flow chart illustrating a method for making a semiconductor system, in accordance with some embodiments.

FIG. 16 is a Y-axis cross-sectional view of the semiconductor system after deposition of a second barrier layer upon exposed surfaces of the first sidewall(s) and the filled trenches.

FIG. 17 is a Y-axis cross-sectional view of the semiconductor system after deposition of a mirror layer.

FIG. 18 is a Y-axis cross-sectional view of the semiconductor system after planarization to remove excess material and for electrical isolation.

FIG. 19 is a Y-axis cross-sectional view of the semiconductor system after deposition of a second dielectric layer.

FIG. 20 is a Y-axis cross-sectional view of the semiconductor system after patterning of a fourth mask layer.

FIG. 21 is a Y-axis cross-sectional view of the semiconductor system after formation of second sidewall(s) above and around the device structure(s) and the testing structure.

FIG. 22 is a Y-axis cross-sectional view of the semiconductor system after deposition of one or more LED layers.

FIG. 23 is a Y-axis cross-sectional view of the semiconductor system after planarization to remove excess material and for electrical isolation.

FIG. 24 is a Y-axis cross-sectional view of the semiconductor system, showing the chip area (containing device structure(s)) and the testkey area (containing the testing structure).

FIG. 25 is a Y-axis cross-sectional view of a second embodiment of the semiconductor system, having a second testing structure in a peripheral area of the chip area.

FIG. 26 is a flow chart illustrating a method for testing a semiconductor system, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Numerical values in the specification and claims of this application should be understood to include numerical values which are the same when reduced to the same number of significant figures and numerical values which differ from the stated value by less than the experimental error of conventional measurement technique of the type described in the present application to determine the value. All ranges disclosed herein are inclusive of the recited endpoint.

The term “about” can be used to include any numerical value that can vary without changing the basic function of that value. When used with a range, “about” also discloses the range defined by the absolute values of the two endpoints, e.g. “about 2 to about 4” also discloses the range “from 2 to 4.” The term “about” may refer to plus or minus 10% of the indicated number.

The present disclosure relates to structures which are made up of different layers. When the terms “on” or “upon” are used with reference to two different layers (including the substrate), they indicate merely that one layer is on or upon the other layer. These terms do not require the two layers to directly contact each other, and permit other layers to be between the two layers. For example all layers of the structure can be considered to be “on” the substrate, even though they do not all directly contact the substrate. The term “directly” may be used to indicate two layers directly contact each other without any layers in between them. In addition, when referring to performing process steps to the substrate or upon the substrate, this should be construed as performing such steps to whatever layers may be present on the substrate as well, depending on the context.

The term “semiconductor die”, or “chip”, or “microchip” are used interchangeably in the present disclosure to refer to the combination of a substrate and the multiple layers upon the substrate which form one or more integrated circuits.

The term “semiconductor package”, as used in the present disclosure, refers to the combination of a semiconductor die and an interconnect layer that permits the semiconductor die to communicate with one or more other packages. Examples of an interconnect layer may include a redistribution layer (RDL) or an interposer having bond pads or C4 bumps or pillars. Thus, a semiconductor package may have an interconnect layer on only one side, or on both sides, as will be seen further herein. It is noted that in the art, the term “package” is used to refer to many different structures and does not have a single fixed definition.

The present disclosure relates to testing structures for use on semiconductor wafer substrates. Testing structures are used to perform testing of the chips formed on the wafer substrate to ensure they operate as intended or desired, and to identify defects. They include electrically conductive materials, particularly copper. However, at high temperatures (about 400° C. or above), copper migration can occur, causing leakage paths and abnormal performance. This in turn can affect Wafer Acceptance Testing (WAT) results, for example parameters such as metal-to-metal spacing (SPA), line resistance (Rs), via resistance (Rc), and junction failure. The testing structures of the present disclosure include a second electrically conductive metal and have a particular shape, for improved system reliability.

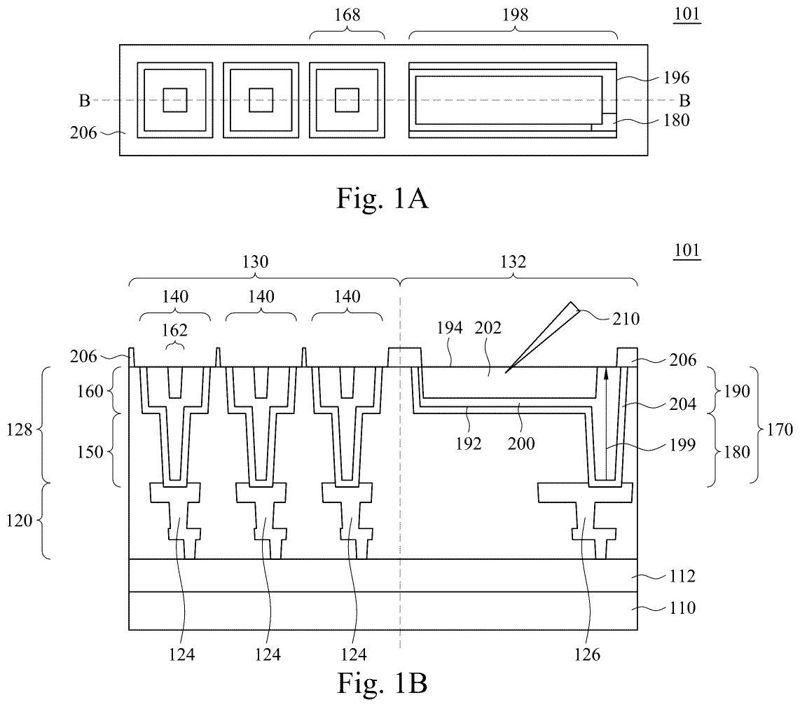

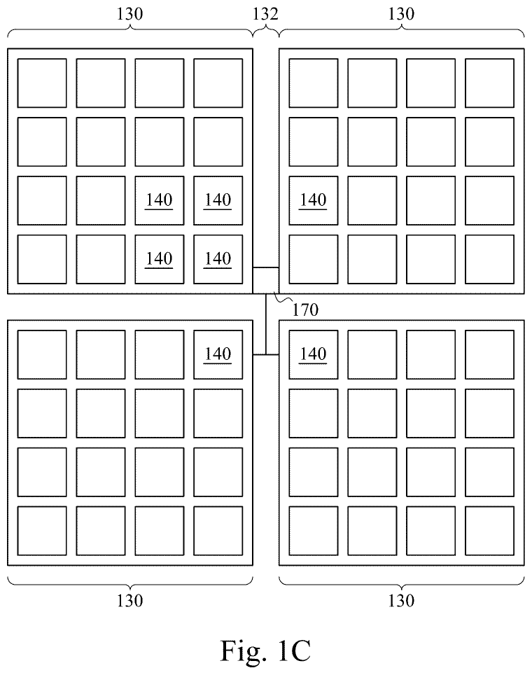

FIG. 1A is a plan view of a semiconductor system 101, in accordance with some embodiments of the present disclosure. FIG. 1B is a Y-axis cross-sectional view through line B-B of FIG. 1A.

Referring to both figures concurrently, the system includes a substrate 110 and multiple layers upon the substrate which form one or more integrated circuits, represented as IC layer 112. These were made during Front-End-Of-Line (FEOL) processes. An interconnect layer 120 is present upon one side of the substrate 110, shown here over the IC layer 112. The interconnect layer 120 includes a dielectric material 122 and electrical interconnections 124, 126 within the dielectric material. The interconnect layer 120 may be formed from several different steps that form several smaller layers that together form the interconnect layer, and may also be considered a redistribution layer (RDL). Generally speaking, the electrical interconnection may be any electrical circuit with any desired structure and made up of any desired components. As illustrated here, a dielectric layer 128 is also present upon the interconnect layer 120. However, the dielectric layer 128 could also be considered part of the interconnect layer 120. These were made during Back-End-Of-Line (BEOL) processes.

The substrate can be divided into multiple chip areas 130 and testkey areas 132, illustrated here with reference to the dotted line. One chip area and one testkey area is illustrated here. One testing structure 170 is present in the testkey area. As illustrated here, three device structures 140 are present in the chip area 130. The testkey area may, in some embodiments, correspond to a scribe line on the substrate, which refers to the spacing between chips/dies where the substrate can be safely cut without damaging the chips/dies. This can be acceptable because the testing structure is not needed after testing has been completed.

The testing structure 170 is formed from a trench 190 which is connected to a via 180. The via can be described as extending from the lower surface 192 of the trench. In addition, the via 180 of the testing structure is located on the perimeter 196 of the trench, or in other words contacts the perimeter. The via 180 also extends through the dielectric layer and contacts an interconnection 126 in the interconnect layer 120. The testing structure may be described as having an L-shape in this cross-sectional view.

A first electrically conductive material 200 fills the via 180, and also forms a layer on the trench 190. The remainder of the trench is filled with a second electrically conductive material 202. It is noted that a conductive path 199 extending vertically from the interconnect layer 120 to an upper surface 194 of the testing structure 170 passes through only the first electrically conductive material 200. The conductive path does not pass through the second electrically conductive material at all. The combination of the two electrically conductive materials forms an electrical pad 198 in the testing structure.

The first electrically conductive material 200 and the second electrically conductive material 202 are different from each other. In some embodiments, the second electrically conductive material is more stable than the first electrically conductive material. This stability may be measured, for example, in terms of the electrically conductive material's susceptibility to migration. For example, in terms of such stability, running from least stable to most stable, Cu<AlCu<AlSiCu<Al<W. in some particular embodiments, the first electrically conductive material is copper, and the second electrically conductive material is AlCu, AlSiCu, Al, or W. In other embodiments, the first electrically conductive material 200 and the second electrically conductive material 202 have different percentages (either wt % or mole %) of a given atom. For example, they may have different percentages of carbon, or copper, or aluminum, or silicon. This can occur, for example, if both electrically conductive materials are alloys.

A first barrier layer 204 is present on the surfaces of the via 180 and the trench 190. The barrier layer may reduce or prevent metal atoms from diffusing into the dielectric layer 128. In some embodiments, the barrier layer may also act as a glue layer that increases adhesion of the first electrically conductive material to the via and the trench.

Referring now to the device structures 140, each device structure 140 also includes a trench 160 which is connected to a via 150. The via 150 also extends through the dielectric layer and contacts an interconnection 124 in the interconnect layer 120. A first barrier layer 204, first electrically conductive material 200, second electrically conductive material 202, and electrical pad 168 are also present, as described with respect to the testing structure 170. One notable difference is that in the device structure 140, the via 150 is located in the central region 162 of the trench 160, rather than along the perimeter of the trench.

As better seen in FIG. 1A, in some particular embodiments, in the device structures 140, the first electrically conductive material 200 has a larger surface area than the second electrically conductive material 202. In contrast, in the testing structure 170, the second electrically conductive material 202 has a larger surface area than the first electrically conductive material 200. This relationship is desirable, but not required. In particular embodiments, the ratio of the surface area of the second electrically conductive material to the surface area of the first electrically conductive material in the device structures is from about 5% to about 20%. In particular embodiments, the ratio of the surface area of the second electrically conductive material to the surface area of the first electrically conductive material in the testing structure is from about 50% to about 95%. However, other ranges and endpoints are within the scope of the present disclosure.

Lastly, one or more sidewalls 206 are present in a layer formed above the filled trenches 160, 190 of the device structure(s) and the testing structure(s), depending on how the sidewalls are considered. For example, each device structure 140 and each testing structure 170 could be considered as having a sidewall 206 around its filled trench. Alternatively, the plan view of FIG. 1A may be considered as showing one sidewall 206 that surrounds each of the filled trenches.

Also illustrated in FIG. 1B is a probe 210. The probe is shown as contacting the electrical pad 198 of the testing structure. This permits testing to be performed, where various electrical parameters can be collected.

In FIG. 1A and FIG. 1B, the interconnection 126 of the testing structure 170 is electrically connected to the interconnections 124 of the device structures 140 through the IC layer 112. It is noted that one testing structure 170 is shown as electrically connected to three device structures 140. However, one testing structure 170 may be electrically connected to any desired number of device structures 140. In addition, those device structures may be organized in any desired configuration, for example, in multiple rows and columns. It is also noted that only one chip area 130 and one testkey area 132 are illustrated. However, the testing structure 170 could be electrically connected more than one chip area. For example, in the plan view of FIG. 1C, the testkey area 132 contains one testing structure 170 that is electrically connected to four different chip areas 130, each chip area containing 16 device structures 140. The testing structure could be electrically connected to all 64 device structures 140. Put another way, the ratio of testing structures to device structures could be any non-zero value.

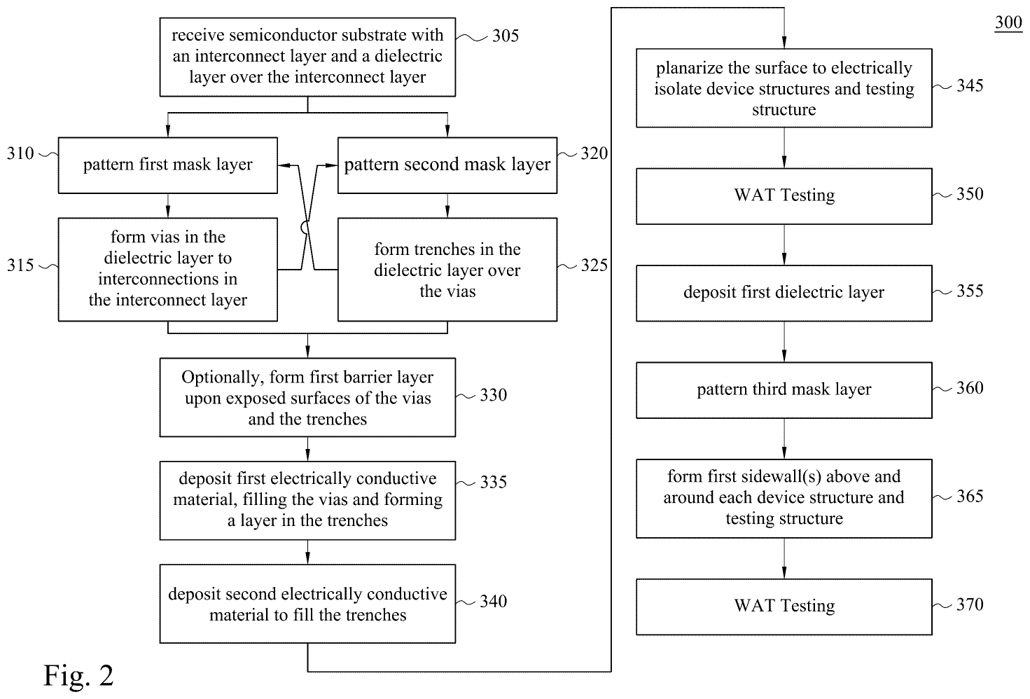

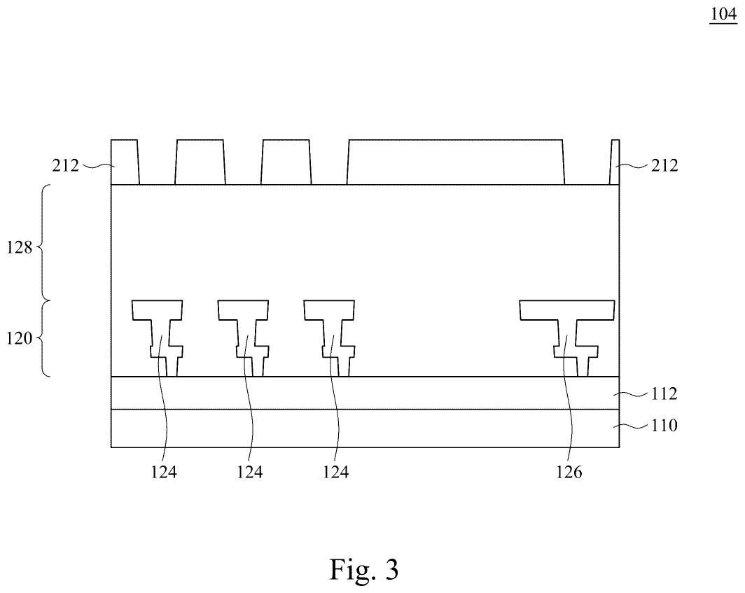

FIG. 2 is a flow chart illustrating a first method 300 for making a testing structure, in accordance with some embodiments. Some steps of the method are also illustrated in FIGS. 3-13. These figures provide different views for better understanding. While the method steps are discussed below in terms of forming a single testing structure relative to a single chip area, such discussion should also be broadly construed as applying to the concurrent formation of multiple testing structures, and/or multiple chip areas. In addition, the method steps are discussed below in terms of forming concurrently forming testing structure(s) and device structures(s), but this is not required. Methods using only some of the steps shown in the flow chart are contemplated as falling within the present disclosure.

Initially, in step 305 of FIG. 2, a semiconductor package is received or provided. Referring to FIG. 3, the semiconductor package 104 includes a substrate 110 and a layer 112 containing one or more integrated circuits. An interconnect layer 120 is present upon the layer of integrated circuit(s), and contains electrical interconnections 124, 126. A dielectric layer 128 is also present upon the interconnect layer 120, and could also be considered part of the interconnect layer 120. In some particular embodiments, the dielectric layer 128 and the dielectric material of the interconnect layer 120 are silicon dioxide (SiO₂).

The substrate is a wafer made of a semiconducting material in certain embodiments. Such semiconductor materials can include silicon, for example in the form of crystalline Si. In alternative embodiments, the substrate can be made of other elementary semiconductors such as germanium, or may include a compound semiconductor such as silicon carbide (SiC), gallium arsenide (GaAs), gallium carbide, gallium phosphide, indium arsenide (InAs), indium phosphide (InP), silicon germanium, silicon germanium carbide, gallium arsenic phosphide, or gallium indium phosphide. In particular embodiments, the wafer substrate is silicon.

Integrated circuits are built up from different patterns of electrically conductive materials and electrically insulating materials to make useful components. Suitable examples of integrated circuit components may include, for example and without limitation, active components (e.g., transistors), passive components (e.g., capacitors, inductors, resistors, and the like), or combinations thereof. These components may be made from electrically conductive materials and electrically insulating materials arranged in various structures.

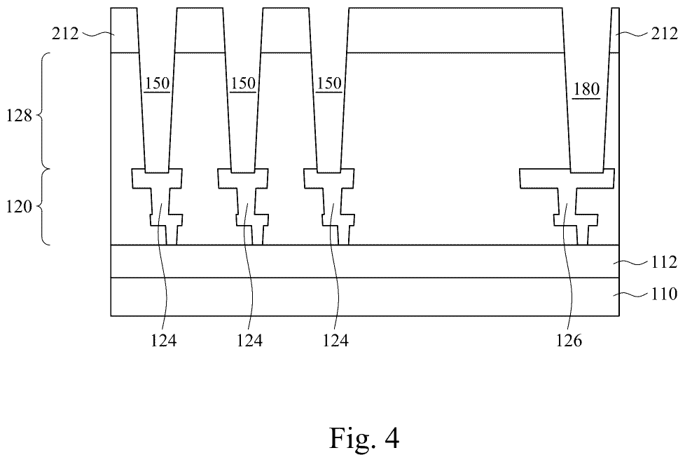

Next, in step 310 of FIG. 2 and as illustrated in FIG. 3, a first mask layer 212 is patterned. The mask layer is typically made of photoresist. Then, in step 315 of FIG. 2 and as illustrated in FIG. 4, vias are formed in the dielectric layer 128 to interconnections in the interconnect layer 120. As indicated here, vias 150 for the device structures and a via 180 for the testing structure are concurrently formed in this step. This may be done, for example, by etching.

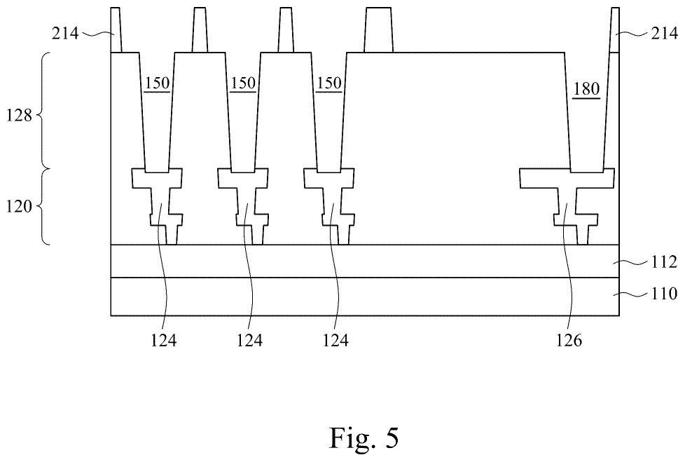

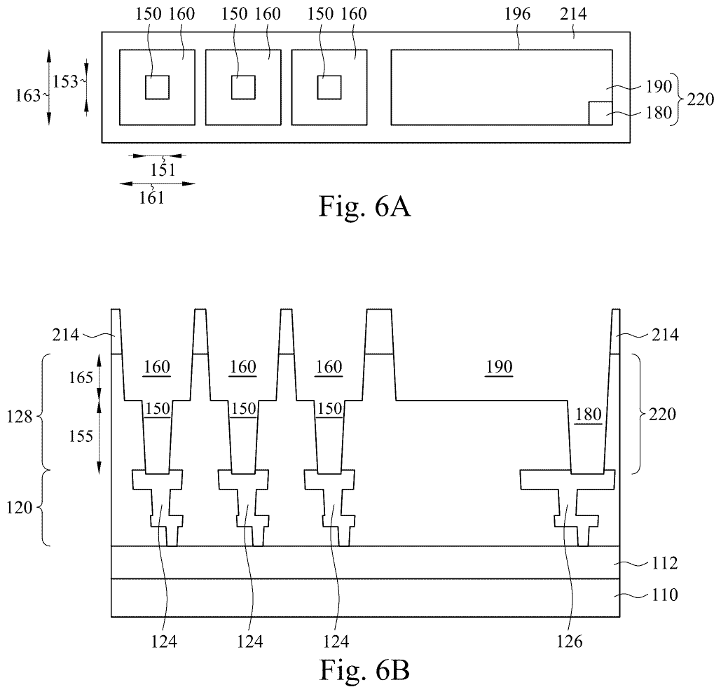

The first mask layer is then removed. Next, in step 320 of FIG. 2 and as illustrated in FIG. 5, a second mask layer 214 is patterned. Again, this mask layer is typically made of photoresist. Then, in step 325 of FIG. 2 and as illustrated in FIG. 6A and FIG. 6B, trenches are formed in the dielectric layer 128 over the vias. As indicated here, trenches 160 for the device structures and a trench 190 for the testing structure are concurrently formed in this step. This may be done, for example, by etching. In addition, the plan view of FIG. 6A more clearly shows that the via 180 of the testing structure is located on the perimeter 196 of the trench. The combination of the via 180 and the trench 190 for the testing structure is also referred to as an intermediate structure 220.

Each device structure via 150 has a length 151, a width 153, and a height 155. In particular embodiments, the length 151 and the width 153 may independently range from about 5 nanometers (nm) to about 200 micrometers (μm). The height 155 may vary as needed. Other ranges and values are within the scope of the present disclosure. Different device structures may have different dimensions.

Each device structure trench 160 has a length 161, a width 163, and a height 165. In particular embodiments, the length 161 and the width 163 may independently range from about 5 nanometers (nm) to about 200 micrometers (μm). The height 165 may range from about 200 angstroms to about 300,000 angstroms (30 μm). Other ranges and values are within the scope of the present disclosure. Different device structures may have different dimensions. The length and width dimensions of the device structure via are less than those of the device structure trench.

As indicated in FIG. 2, it is also contemplated that the trenches 160, 190 are formed first, and then the vias 150, 180 are formed. In this situation, mask layers of different shapes would be used.

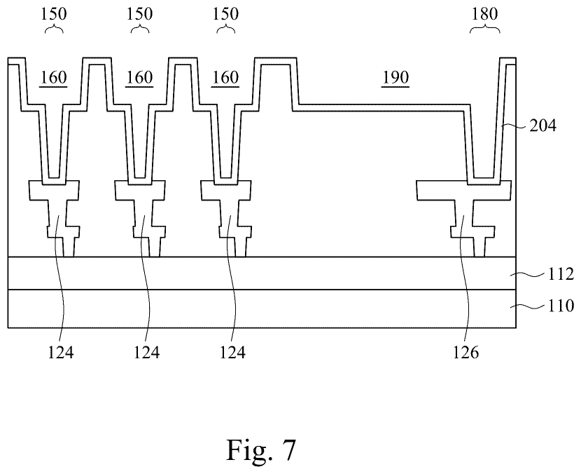

Next, in optional step 330 of FIG. 2 and as illustrated in FIG. 7, a first barrier layer 204 is applied over the substrate 110. The first barrier layer is formed upon the exposed surfaces of the vias 150, 180 and the trenches 160, 190 of the device structure(s) and the testing structure(s). In particular embodiments, the first barrier layer may be formed from TiN, TaN, W, Ti, or Ta, or other suitable material. The first barrier layer is typically formed by chemical vapor deposition (CVD), physical vapor deposition (PVD), atomic layer deposition (ALD), or other suitable methods.

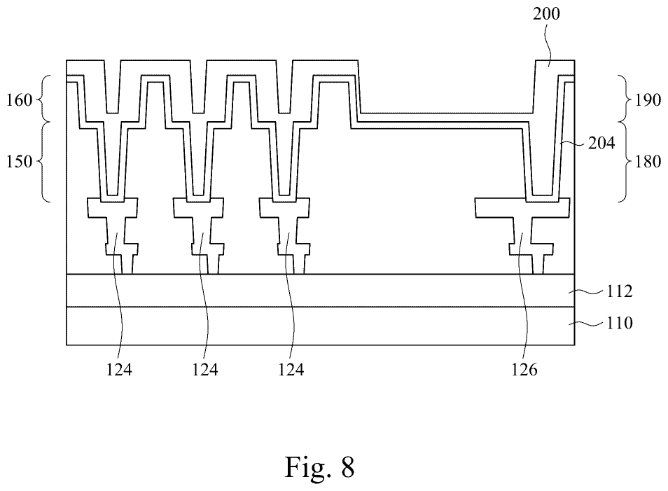

Next, in step 335 of FIG. 2 and as illustrated in FIG. 8, a first electrically conductive material 200 is applied over the substrate, especially the vias 150, 180 and the trenches 160, 190. This deposition may be performed, for example, by evaporation, sputtering, electrochemical plating (ECP), CVD, PVD, ALD, or other suitable methods. In particular embodiments, the first electrically conductive material is applied via electrochemical plating. The vias 150, 180 are filled with the first electrically conductive material. A layer of the first electrically conductive material is formed in the trenches 160, 190. It is particularly noted that because the testing structure via 180 is formed on the perimeter of the testing structure trench 190, the portion of the trench above the via is covered by the first electrically conductive material.

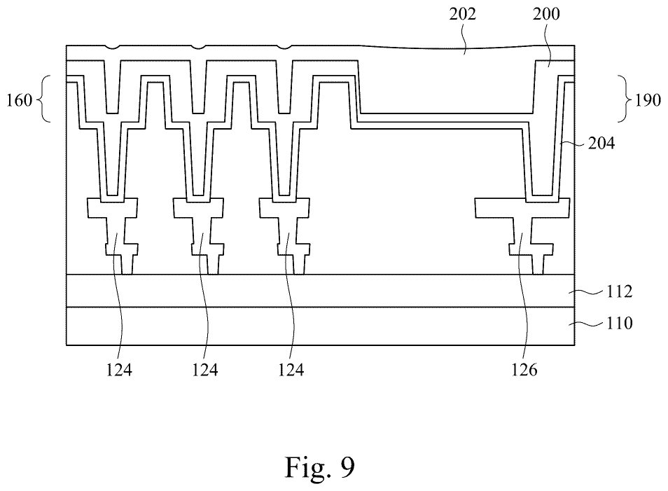

Then, in step 340 of FIG. 2 and as illustrated in FIG. 9, a second electrically conductive material 202 is applied over the substrate 110. The second electrically conductive material fills the trenches 160, 190. Again, this deposition may be performed, for example, by evaporation, sputtering, electrochemical plating (ECP), CVD, PVD, ALD, or other suitable methods. In particular embodiments, the second electrically conductive material is applied via electrochemical plating.

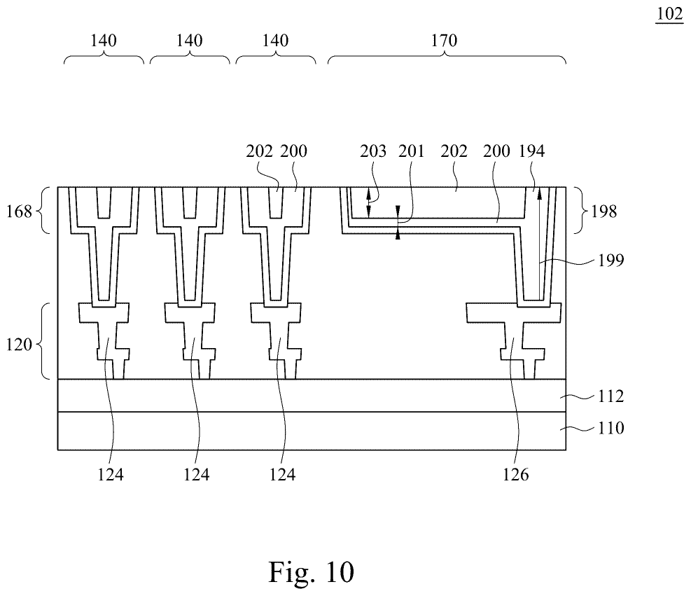

Continuing, in step 345 of FIG. 2 and as illustrated in FIG. 10, the surface of the substrate is planarized to electrically isolate the device structures 140 and the testing structure 170. This may be done, for example, by chemical mechanical polishing (CMP), where the surface of a wafer is leveled using relative motion between the wafer and a rotating polishing pad to which a slurry is applied. Downward pressure is applied to push the wafer against the polishing pad, and elevated elements are worn down to obtain a surface with low surface roughness. As illustrated in FIG. 10, the substrate is planarized such that portions of the first barrier layer joining the various device structures 140 and the testing structure 170 together are removed. Electrical pads 168, 198 are formed from the combination of the first electrically conductive material and the second electrically conductive material. In the testing structure, a conductive path 199 extends vertically from the interconnect layer 120/interconnection 126 to an upper surface 194 of the testing structure, which passes through only the first electrically conductive material 200. Put another way, the conductive path 199 does not pass through the second electrically conductive material 202.

In particular embodiments, the height 201 of the first electrically conductive material in the trench 190 may range from about 100 angstroms to about 150,000 angstroms (15 μm). In particular embodiments, the height 203 of the second electrically conductive material in the trench 190 may range from about 100 angstroms to about 150,000 angstroms (15 μm). In particular embodiments, the ratio of the second electrically conductive material height 203 to the first electrically conductive material height 201 may range from about 100:150,000 to about 150,000:100. In more specific embodiments, the ratio is from about 1:1 to about 1500:1 (i.e. the second electrically conductive material height 203 is greater). However, other ranges and endpoints for these heights and ratios are within the scope of the present disclosure. It is also noted that due to the different dimensions of the trenches 160 in the device structures 140, the heights of these two layers may differ from that of the testing structure 170.

As indicated in step 350 of FIG. 2, the testing structure 170 may be considered complete in some embodiments, and WAT testing of the device structures 140 that are electrically connected to the testing structure 170 may be performed. Thus, in some embodiments, the system of FIG. 10 may be considered a semiconductor system 102.

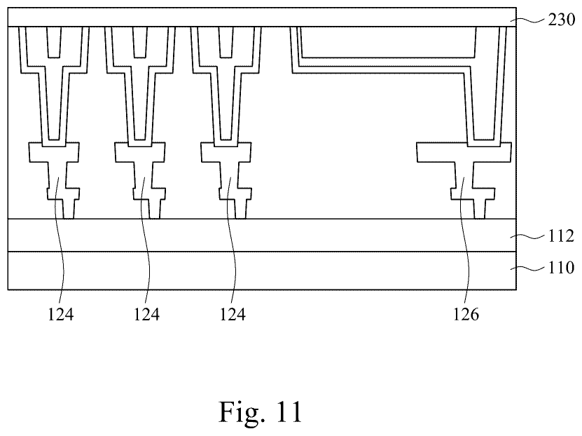

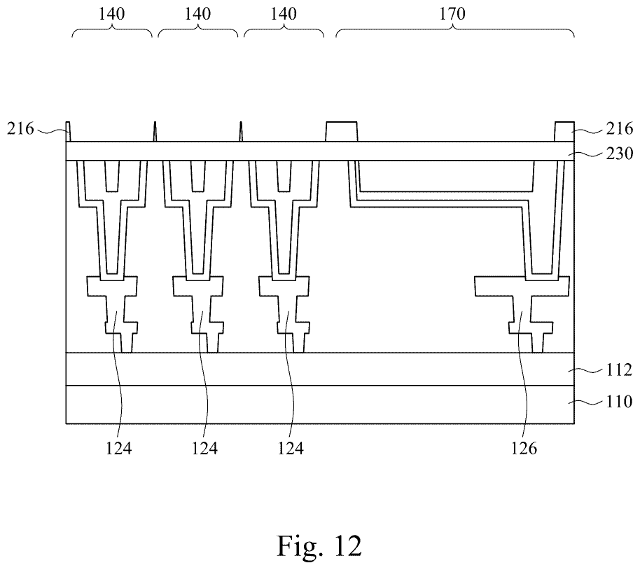

In some additional embodiments, additional components can be added to the testing structure. In step 355 of FIG. 2 and as illustrated in FIG. 11, a first dielectric layer 230 is formed over the substrate 110. This may be done by CVD, PVD, or other suitable deposition methods. Then, in step 360 of FIG. 2 and as illustrated in FIG. 12, a third mask layer 216 is patterned.

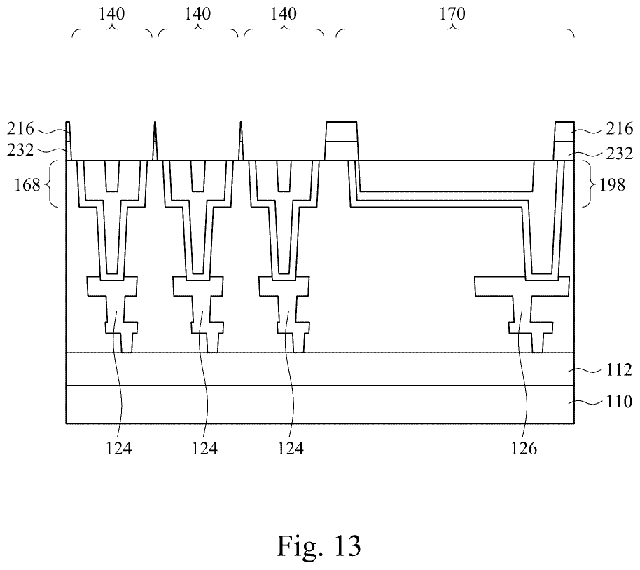

Next, in step 365 of FIG. 2 and as illustrated in FIG. 13, etching is performed to formed one or more first sidewalls 232 around each device structure 140, as well as around the testing structure 170. After the third mask layer is removed, the resulting structure is illustrated in FIG. 1A and FIG. 1B. It should be noted that the first sidewall(s) may or may not cover some portion of the electrical pads 168, 198 in the device structures 140 and the testing structure 170. WAT testing of the device structures 140 that are electrically connected to the testing structure 170 may alternatively be performed now, as indicated in step 370 of FIG. 2.

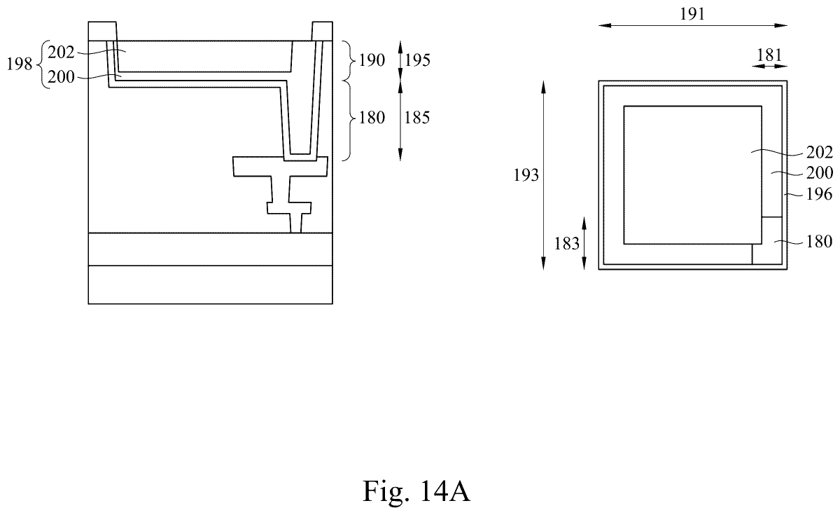

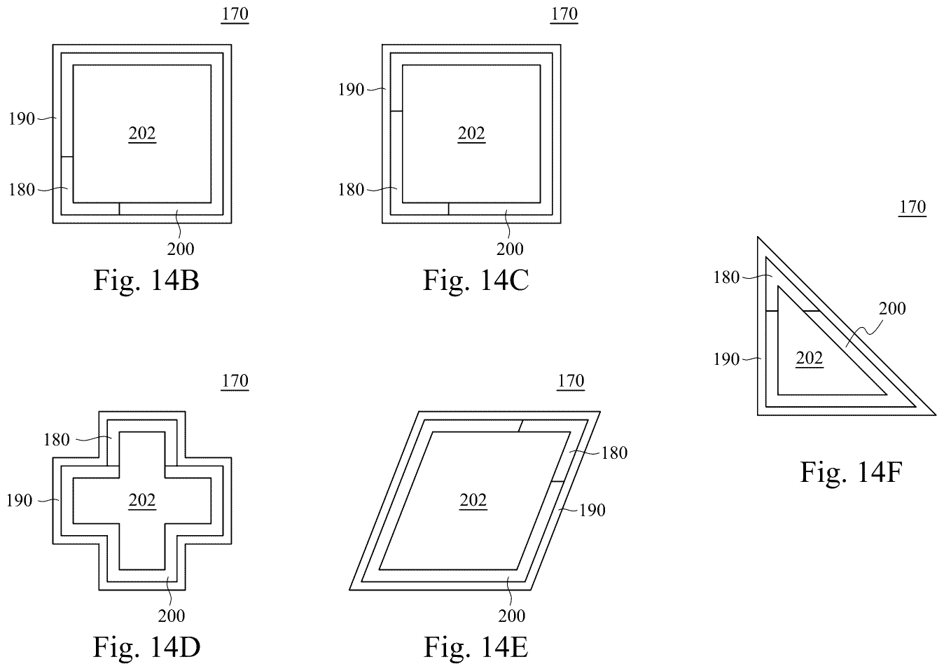

FIG. 14A is a view illustrating how the various layers of the testing structure correspond to each other from a Y-axis cross-sectional to a plan view, in one embodiment of the testing structure. As illustrated here, in the plan view, the second electrically conductive material 202 is the majority of the exposed surface area of the electrical pad 198, with the first electrically conductive material 200 forming a square annulus around the center. The via 180 is illustrated as being located on the perimeter 196 of the trench 190, and has a rectangular shape.

Referring to FIG. 14A, the testing structure via 180 has a length 181, a width 183, and a height 185. In particular embodiments, the length 181 and the width 183 may independently range from about 5 nanometers (nm) to about 200 micrometers (μm). The height 185 may vary as needed. Other ranges and values are within the scope of the present disclosure. Different testing structures may have different dimensions.

The testing structure trench 190 has a length 191, a width 193, and a height 195. In particular embodiments, the length 191 and the width 193 may independently range from about 5 nanometers (nm) to about 200 micrometers (μm). The height 195 may range from about 200 angstroms to about 300,000 angstroms (30 μm). Other ranges and values are within the scope of the present disclosure. Different testing structures may have different dimensions. The length and width dimensions of the testing structure via are less than those of the testing structure trench. In particular embodiments, the ratio of the testing structure trench length 191 to the testing structure via length 181 is from about 4:1 to about 40,000:1 (i.e. the trench is larger than the via). In particular embodiments, the ratio of the testing structure trench width 193 to the testing structure via width 183 is from about 4:1 to about 40,000:1 (i.e. the trench is larger than the via). However, other ranges and endpoints are within the scope of the present disclosure.

Referring back to FIG. 6A, it is noted the length and width dimensions of the device structure trench 160 are typically much smaller than the length and width dimensions of the testing structure trench 190, because the testing structure must accommodate the size of the probe that will be used for testing.

In particular embodiments, the ratio of the testing structure trench length 191 to the device structure trench length 161 may be from about 1:1 to about 40,000:1 (i.e. the testing structure is much longer than the device structure). In particular embodiments, the ratio of the testing structure trench width 193 to the device structure trench length 163 is also from about 1:1 to about 40,000:1. However, other ranges and endpoints are within the scope of the present disclosure. In some more particular embodiments, as best seen in FIG. 6A, the device structure and the testing structure have the same value in one of the dimensions (length or width). However, this is not required.

FIGS. 14B-14F are plan views showing some variations in the shape of the testing structure 170. In the variation of FIG. 14B, the trench 190 has a rectangular (more specifically, square) shape. The via 180 also has a rectangular (more specifically, square) shape. Compared to the embodiment of FIG. 14A, the via is located in a different corner. In the variation of FIG. 14C, the trench 190 has a square shape, while the via 180 has a different rectangular shape (the sides have different lengths). In the variation of FIG. 14D, the trench 190 is in the shape of a cross, while the via 180 has a rectangular shape. In the variation of FIG. 14E, the trench 190 and the via 180 are both in the shape of a parallelogram. In the variation of FIG. 14F, the trench 190 and the via 180 are both in the shape of a triangle. More generally, the shape of the trench 190 and the via 180 for the testing structure, when seen from the plan view, may be independent of each other. In addition, the via 180 for the testing structure may be located anywhere relative to the chip area.

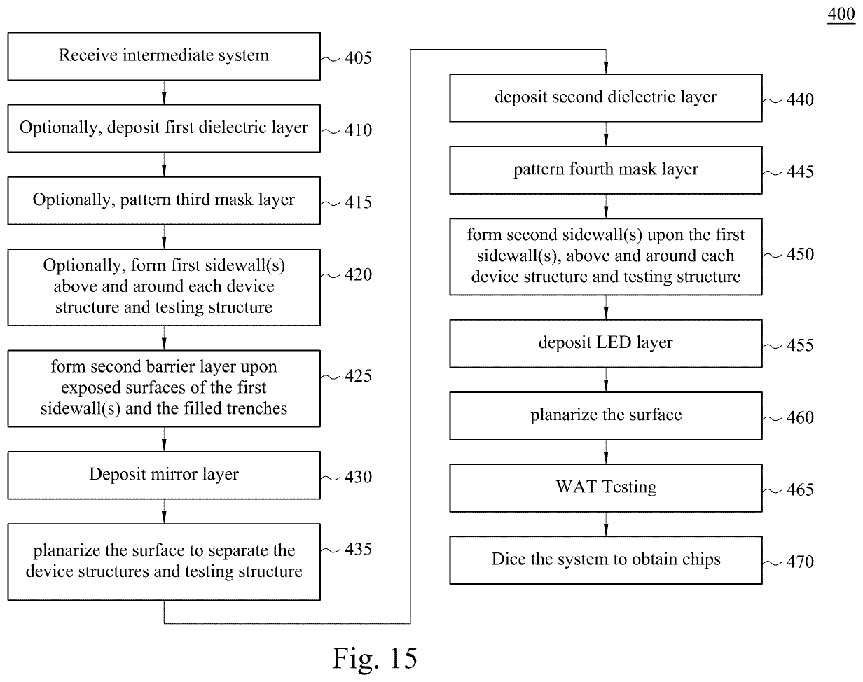

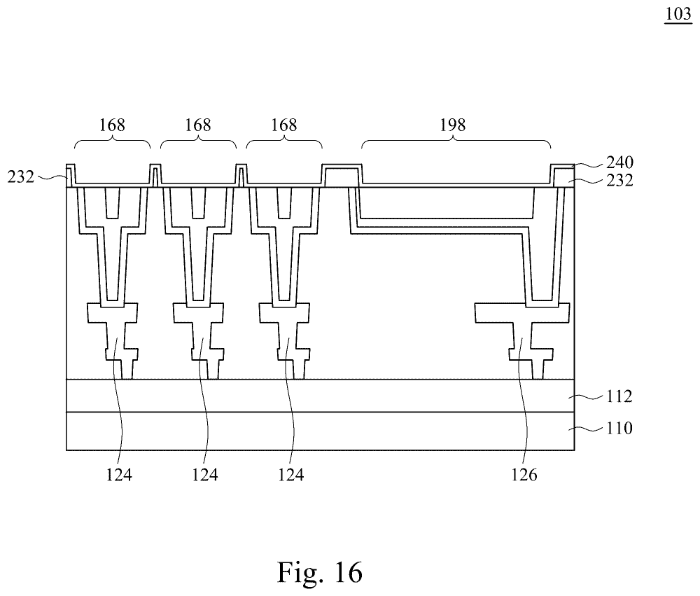

It is noted that the semiconductor systems 101, 102 illustrated in FIG. 1B and FIG. 10 respectively are located on semiconductor wafer substrates, and the wafers have not yet been diced into individual chips. In some embodiments, these semiconductor systems can be considered intermediate systems 103, and further processing can be performed. FIG. 15 is a flow chart illustrating a method 400 for making a semiconductor system such as a set of light-emitting diodes (LEDs), in accordance with some embodiments. Some steps of the method are also illustrated in FIGS. 16-23. Again, the discussion below should be broadly construed, and methods using only some of the steps shown in the flow chart are contemplated as falling within the present disclosure.

Initially, in step 405 of FIG. 15, an intermediate system 103, such as that illustrated in FIG. 1B or FIG. 10, is received or provided. The intermediate systems have passed WAT testing, indicating that the device structures 140 have electrical parameters within acceptable values and/or tolerances. If the structure of FIG. 10 is received, then optional steps 410, 415, 420 of FIG. 15 are performed to obtain the structure of FIG. 1B having first sidewall(s) 232.

Next, in step 425 of FIG. 15 and as illustrated in FIG. 16, a second barrier layer 240 is applied over the substrate. The second barrier layer is formed upon the exposed surfaces of the first sidewall(s) 232 and the electrical pads 168, 198 of the device structure(s) and the testing structure(s). In particular embodiments, the second barrier layer may be formed from TiN, TaN, W, Ti, or Ta, or other suitable material. The second barrier layer can be formed by CVD, PVD, ALD, or other suitable methods.

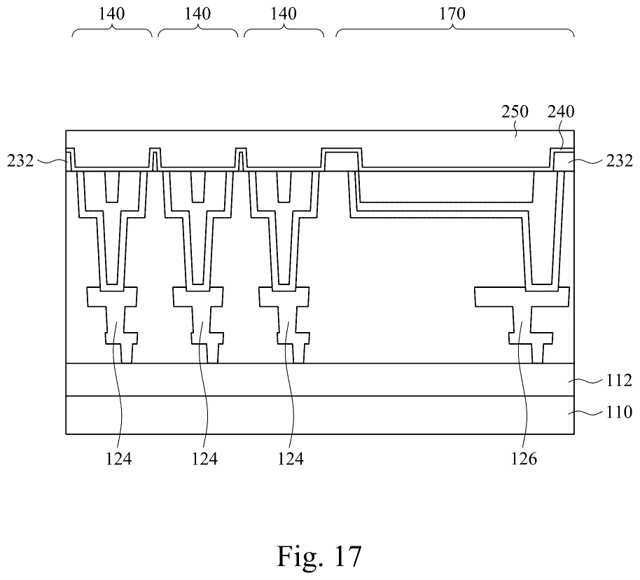

Then, in step 430 of FIG. 15 and as illustrated in FIG. 17, a mirror layer 250 is deposited over the substrate, and especially over the device structures 140. Generally, the mirror layer is intended to reflect light, and desirably has a reflectivity of 80% or more for wavelengths of about 350 nm to about 780 nm. Some non-limiting examples of materials that may be suitable for the mirror layer include W, Cu, Al, AlCu, and AlSiCu. The mirror layer can be formed by CVD, PVD, ALD, or other suitable methods.

In particular embodiments, the length and the width of the mirror layer may independently range from about 5 nanometers (nm) to about 200 micrometers (μm). The height 255 may range from about 100 angstroms to about 150,000 angstroms (15 μm). Other ranges and values are within the scope of the present disclosure.

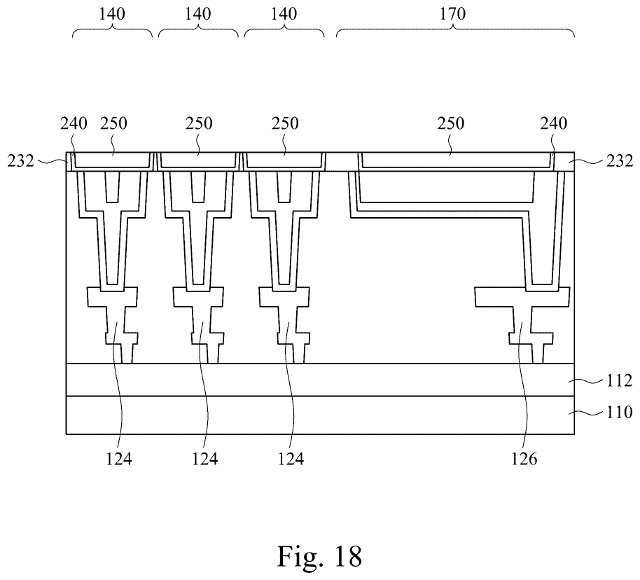

Next, in step 435 of FIG. 15 and as illustrated in FIG. 18, the surface of the substrate is planarized to electrically isolate the device structures 140 and the testing structure 170. This may be done, for example, by CMP. As illustrated, the substrate is planarized such that excess mirror layer material and portions of the second barrier layer joining the various device structures 140 and the testing structure 170 together are removed. It is noted that the mirror layer 250 formed in the testing structure 170 may differ in shape from the mirror layer in the device structures 140, and might not be used in the final device.

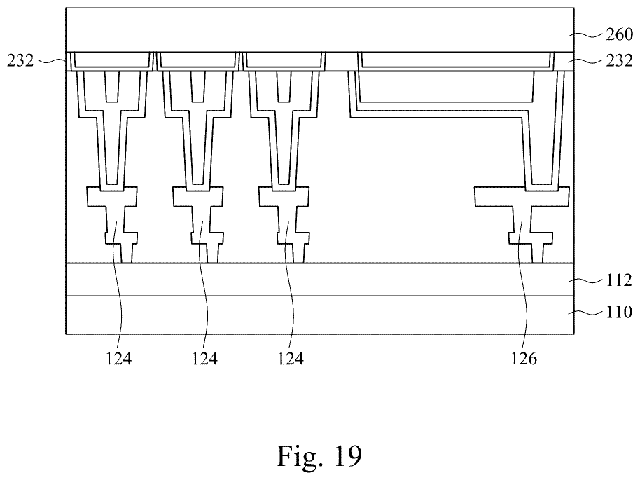

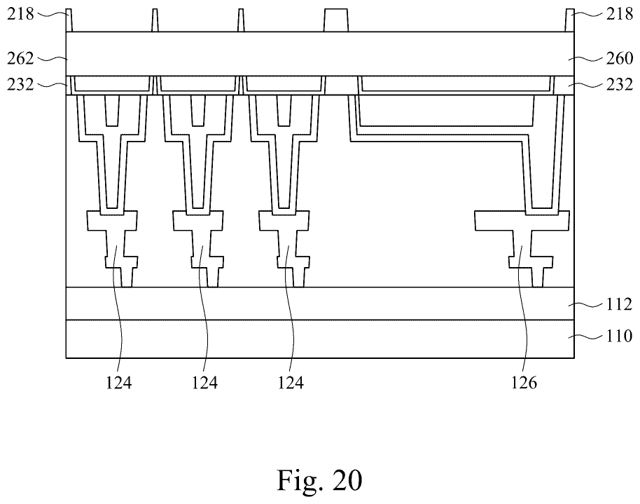

Continuing, in step 440 of FIG. 15 and as illustrated in FIG. 19, a second dielectric layer 260 is formed over the substrate 110. This may be done by CVD, PVD, or other suitable deposition methods. Then, in step 445 of FIG. 15 and as illustrated in FIG. 20, a fourth mask layer 218 is patterned. It is particularly contemplated that in some embodiments, the patterning does not expose the testing structure 170 at all.

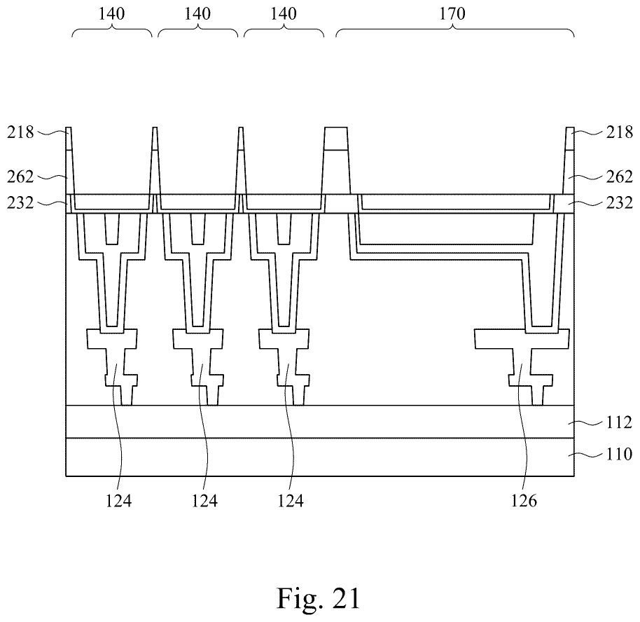

Next, in step 450 of FIG. 15 and as illustrated in FIG. 21, etching is performed to formed one or more second sidewall(s) 262 around each device structure 140, and optionally around the testing structure 170. The second sidewall(s) may be considered as being placed over the first sidewall(s). The combination of the first sidewall(s) 232 and the second sidewall(s) 262 correspond to the sidewalls 206 of FIG. 1B.

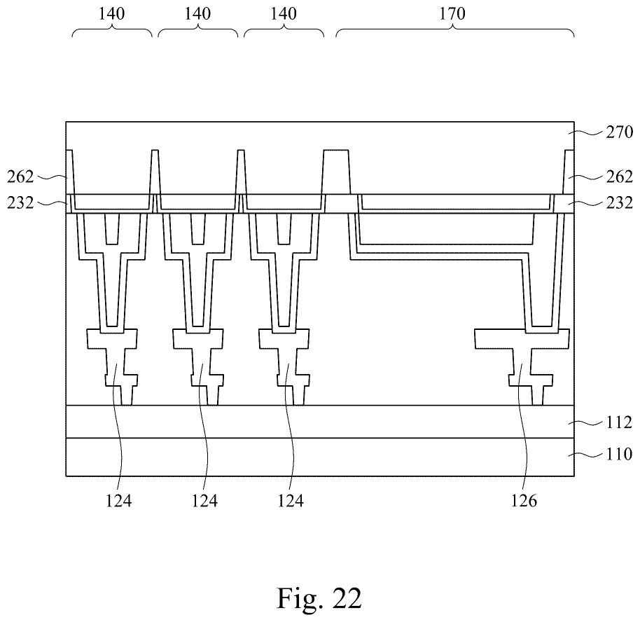

Next, in step 455 of FIG. 15 and as illustrated in FIG. 22, one or more light-emitting diode (LED) layers 270 are deposited. In some particular embodiments, one or more organic LED materials are present in the LED layer. In some particular embodiments, the LED layer is adapted or configured to emit white light. The LED layer may, for example, be a multilayer structure, where different layers emit a specific color and the multilayer structure outputs light spanning the visible range (of about 380 nm to about 700 nm). The LED layer may be formed by suitable combinations of deposition and doping, or by crystalline growth, or by solution processing of appropriate materials (organic and/or inorganic). The LED layer may also include, for example, a transparent electrically conductive layer, such as indium tin oxide, that acts as a second electrode. The LED layer may also include a color filter, so that each device structure 140 emits light of a desired or different color.

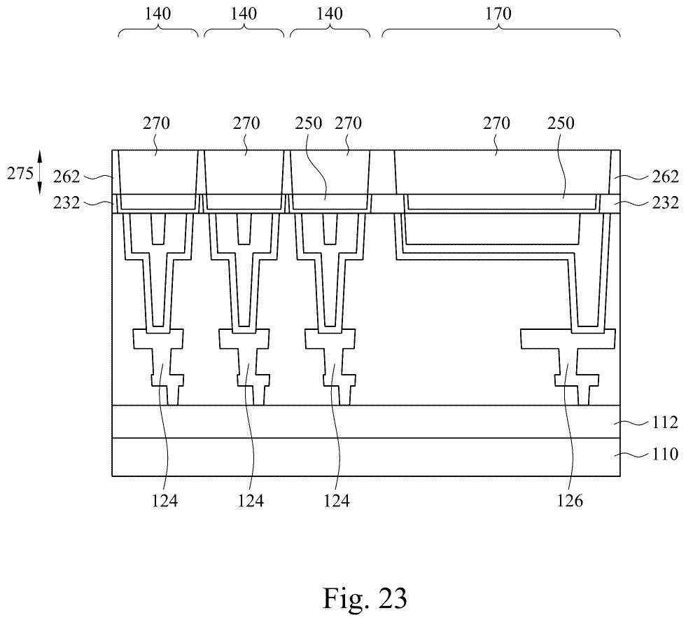

Excess material from the LED layer may be present over the substrate. In step 460 of FIG. 15 and as illustrated in FIG. 23, then, the surface of the substrate may be planarized to electrically isolate the device structures 140 and the testing structure 170. This may be done, for example, by CMP. The resulting LED layer 270 is bounded by the second sidewall(s). In particular embodiments, the length and the width of the LED layer may independently range from about 5 nanometers (nm) to about 200 micrometers (μm). The height 275 may range from about 100 angstroms to about 150,000 angstroms (15 μm). Other ranges and values are within the scope of the present disclosure. As illustrated here, the LED layer 270 in the device structures 140 are located over the mirror layer 250, but in the testing structure 170 the LED layer extends past the mirror layer and over the sidewalls 232. Such differences in structure may occur (for example due to process deviation), and are not required. In some embodiments, an LED layer is not formed in the testing structure 170 at all.

As indicated in step 465 of FIG. 15, WAT testing of the device structures 140 that are electrically connected to the testing structure 170 may again be performed. If the device structures 140 are on the substrate 110, then further processing may be performed. For example, in step 470 of FIG. 15, the substrate is diced through scribe lines to obtain chips having the device structures thereon. If the testing structures 170 are in the scribe line, then they may be destroyed during dicing.

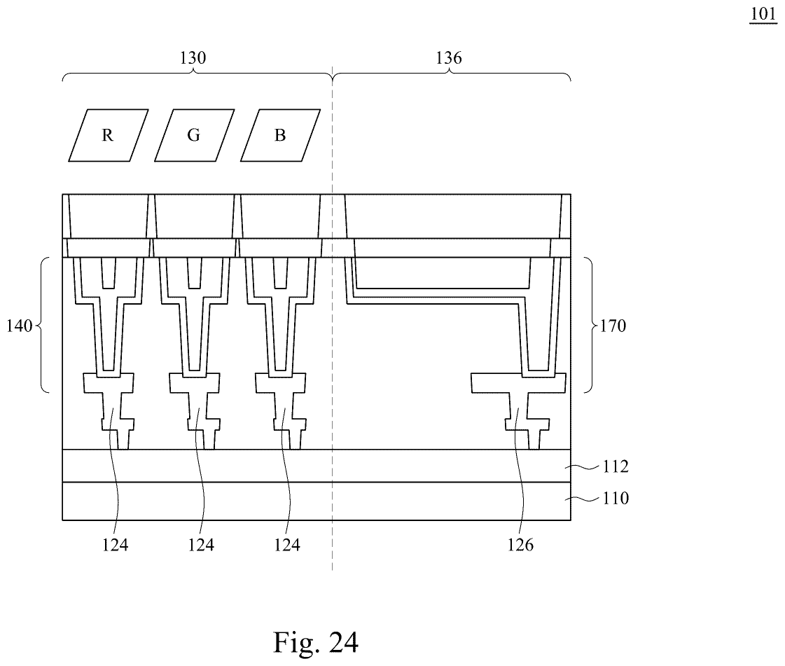

FIG. 24 is a side cross-sectional view of the resulting semiconductor system 101. The chip area 130 includes device structures 140 that are illustrated here as pixels of different colors (red, green, blue). The testing structure 170 is formed in a testkey area which may correspond to the scribe line 136.

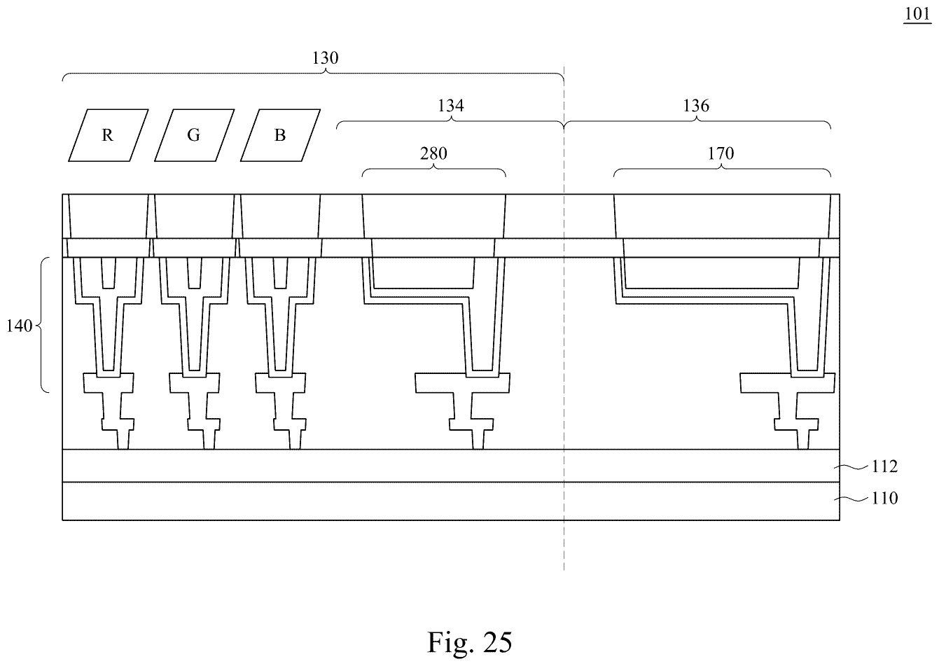

FIG. 25 is a side cross-sectional view of a second embodiment of the semiconductor system 101. Here, two testing structures 170, 280 are present. One testing structure 170 is in the scribe line 136. The second testing structure 280 is in a peripheral area 134 of the chip area 130. The peripheral area is adjacent the scribe line 136. The dimensions of the two testing structures may be the same or different, as desired. The two testing structures could monitor different parameters in the same area, or could monitor the same parameters in different areas, or different parameters in different areas. Embodiments where one testing structure is formed in the peripheral area of the chip area are also within the scope of the present disclosure.

The structures and methods of the present disclosure discussed above refer to dielectric layers. Such dielectric layers can generally be made from any suitable dielectric material or combination thereof, although the characteristics of any particular layer may also be further defined. Examples of dielectric materials may include silicon dioxide (SiO₂), silicon nitride (Si₃N₄), silicon carbide (SiC), hafnium dioxide (HfO₂), zirconium dioxide (ZrO₂), aluminum oxide (Al₂O₃), silicon oxynitride (SiOₓN_{y}), hafnium oxynitride (HfOₓN_{y}) or zirconium oxynitride (ZrOₓN_{y}), or hafnium silicates (HfSiₓO_{y}) or zirconium silicates (ZrSiₓO_{y}) or silicon carboxynitride (SiCₓO_{y}N_{z}), or hexagonal boron nitride (hBN). Other dielectric materials may include tantalum oxide (Ta₂O₅), nitrides such as silicon nitride, polysilicon, phosphosilicate glass (PSG), fluorosilicate glass (FSG), undoped silicate glass (USG), high-stress undoped silicate glass (HSUSG), and borosilicate glass (BSG). They may be low-k dielectrics, extremely low-k dielectrics, or high-k dielectrics. The dielectric layer may be formed by any suitable means, including chemical vapor deposition (CVD), physical vapor deposition (PVD), atomic layer deposition (ALD), thermal oxidation, or other suitable methods.

Any electrically conductive material discussed herein may generally be any conductive metal or conductive oxide. Examples of suitable metals may include copper, aluminum, nickel, chromium, gold, germanium, silver, titanium, tungsten, platinum, tantalum, ruthenium, cobalt, rhenium, palladium, or zirconium; composites like TiN, WN, or TaN; or alloys thereof like AlCu. Examples of suitable conductive oxides may include indium tin oxide (ITO), zinc oxide (ZnO), tin oxide (SnO), aluminum zinc oxide (AlZnO), indium oxide (InO), or cadmium oxide (CdO). The metal or oxide material may be deposited, for example, via evaporation or sputtering, plating, chemical vapor deposition (CVD), physical vapor deposition (PVD), atomic layer deposition (ALD), or other suitable methods.

It is also noted that certain conventional steps are not expressly described in the discussion above. For example, a pattern/structure may be formed in a given layer by applying a photoresist layer, patterning the photoresist layer, developing the photoresist layer to form a mask, and then etching through the mask to transfer the pattern to the given layer.

Generally, a photoresist layer may be applied, for example, by spin coating, or by spraying, roller coating, dip coating, or extrusion coating. Typically, in spin coating, the substrate is placed on a rotating platen, which may include a vacuum chuck that holds the substrate in plate. The photoresist composition is then applied to the center of the substrate. The speed of the rotating platen is then increased to spread the photoresist evenly from the center of the substrate to the perimeter of the substrate. The rotating speed of the platen is then fixed, which can control the thickness of the final photoresist layer.

Next, the photoresist composition is baked or cured to remove the solvent and harden the photoresist layer. In some particular embodiments, the baking occurs at a temperature of about 90° C. to about 110° C. The baking can be performed using a hot plate or oven, or similar equipment. As a result, the photoresist layer is formed on the substrate.

The photoresist layer is then patterned via exposure to radiation. The radiation may be any light wavelength which carries a desired mask pattern. In particular embodiments, EUV light having a wavelength of about 13.5 nm is used for patterning, as this permits smaller feature sizes to be obtained. This results in some portions of the photoresist layer being exposed to radiation, and some portions of the photoresist not being exposed to radiation. This exposure causes some portions of the photoresist to become soluble in the developer and other portions of the photoresist to remain insoluble in the developer.

An additional photoresist bake step (post exposure bake, or PEB) may occur after the exposure to radiation. For example, this may help in releasing acid leaving groups (ALGs) or other molecules that are significant in chemical amplification photoresist.

The photoresist layer is then developed using a developer. The developer may be an aqueous solution or an organic solution. The soluble portions of the photoresist layer are dissolved and washed away during the development step, leaving behind a photoresist pattern (i.e. a mask). One example of a common developer is aqueous tetramethylammonium hydroxide (TMAH). Generally, any suitable developer may be used. Sometimes, a post develop bake or “hard bake” may be performed to stabilize the photoresist pattern after development, for optimum performance in subsequent steps.

Continuing, portions of the given layer below the patterned photoresist mask are now exposed. Etching transfers the photoresist pattern to the given layer below the patterned photoresist mask. After use, the mask can be removed, for example, using various solvents such as N-methyl-pyrrolidone (NMP) or alkaline media or other strippers at elevated temperatures, or by dry etching using oxygen plasma.

Generally, any etching step described herein may be performed using wet etching, dry etching, or plasma etching processes such as reactive ion etching (RIE) or inductively coupled plasma (ICP), or combinations thereof, as appropriate. The etching may be anisotropic. Depending on the material, etchants may include carbon tetrafluoride (CF₄), hexafluoroethane (C₂F₆), octafluoropropane (C₃F₈), fluoroform (CHF₃), difluoromethane (CH₂F₂), fluoromethane (CH₃F), carbon fluorides, nitrogen (N₂), hydrogen (H₂), oxygen (O₂), argon (Ar), xenon (Xe), xenon difluoride (XeF₂), helium (He), carbon monoxide (CO), carbon dioxide (CO₂), fluorine (F₂), chlorine (Cl₂), hydrogen bromide (HBr), hydrofluoric acid (HF), nitrogen trifluoride (NF₃), sulfur hexafluoride (SF₆), boron trichloride (BCl₃), ammonia (NH₃), bromine (Br₂), or the like, or combinations thereof in various ratios. For example, silicon dioxide can be wet etched using hydrofluoric acid and ammonium fluoride. Alternatively, silicon dioxide can be dry etched using various mixtures of CHF₃, O₂, CF₄, and/or H₂.

The semiconductor systems of the present disclosure can be used in several different applications. For example, they could be used in display panels (LED/OLED/LCD), logic devices, random-access-memory (RAM) devices, or image sensors. They may be included in imaging devices such as binoculars, cameras (handheld, still, or video), telescopes, and/or cellphones/smartphones. The device structures, such as those of FIG. 10, could also be used for hybrid bonding between two semiconductor systems/packages, where both a dielectric bond and a metal bond are used to form connections between the two systems/packages.

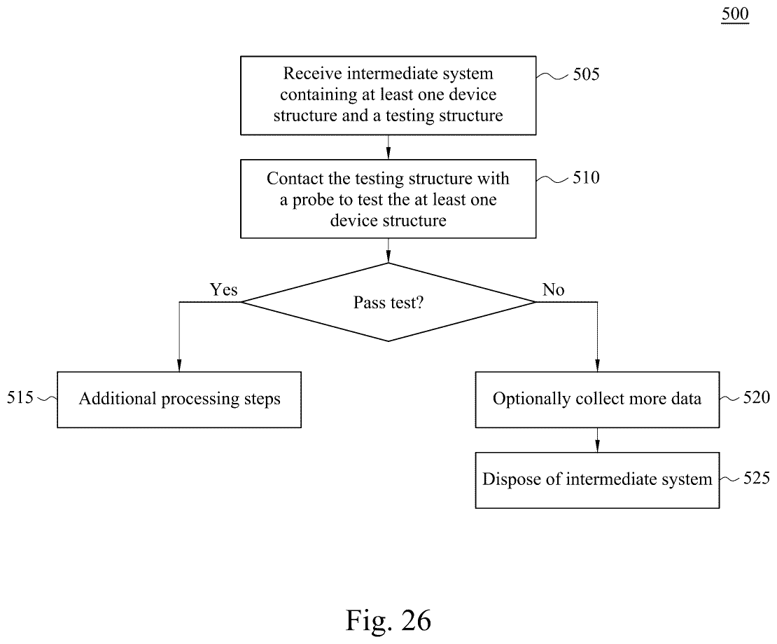

FIG. 26 is a flow chart illustrating a method 500 for testing a semiconductor system, in accordance with some embodiments. This method is performed using a semiconductor system as shown in FIG. 1B or FIG. 10 or FIG. 24 or FIG. 25.

In step 505 of FIG. 26, a semiconductor system is received which includes at least one device structure 140 and at least one testing structure 170. This is generally in the form of device structure(s) on a wafer substrate, and may be an intermediate system. In step 510, the testing structure 170 is contacted with a probe (reference numeral 210 in FIG. 1B) to conduct testing on the device structure(s). If the device structure(s) pass the testing, then additional processing steps may be performed in step 515. These may include the steps described in FIG. 15. If the device structure(s) fail the testing, then in optional step 520, more data may be collected. The semiconductor system may then be disposed of in step 525.

The structures of the present disclosure have several advantages. The presence of the second electrically conductive material over the first electrically conductive material in the testing structure reduces or prevents copper migration during testing, which improves the test results. At the same time, the relatively small amount of the second electrically conductive material compared to the amount of the first electrically conductive material in the device structures means the Rc/Rs of the device structures is not impacted.

Some embodiments of the present disclosure thus relate to methods for making a semiconductor structure. An intermediate structure is formed in a dielectric layer. The intermediate structure comprises a trench connected to a via, the via connecting to an interconnection on a semiconductor substrate. A first electrically conductive material is applied over the intermediate structure to fill the via. A second electrically conductive material is applied to fill the trench of the intermediate structure and obtain the semiconductor structure. A conductive path extending vertically from the interconnect layer to an upper surface of the testing structure passes through only the first electrically conductive material.

Other embodiments disclosed herein relate to semiconductor systems. An interconnect layer on a semiconductor substrate has at least one interconnection in a chip area and an interconnection for a semiconductor structure. A first semiconductor structure is also present on the substrate. The first semiconductor structure comprises a trench and a via connected to the interconnection for the semiconductor structure. The semiconductor structure further comprises: a first electrically conductive material filling the via and forming a layer in the trench; and a second electrically conductive material filling the trench. The via of the semiconductor structure is located on a perimeter of a lower surface of the trench.

In further embodiments, at least one device structure is present in the chip area. The device structure comprises a trench and a via connected to the at least one interconnection in the chip area. The at least one device structure also further comprises: a first electrically conductive material filling the via and forming a layer in the trench; and a second electrically conductive material filling the trench. The via of the semiconductor structure is located on a perimeter of a lower surface of the trench.

Also described in various embodiments herein are methods for testing an intermediate system. An intermediate system is received or provided. The intermediate system may be a semiconductor system as described above, containing a semiconductor structure and at least one device structure. The semiconductor structure is contacted with a probe to conduct testing on the at least one device structure.

Also disclosed herein in various embodiments are devices that contain the testing structure as described above. Such devices may include display panels (LED/OLED/LCD), logic devices, random-access-memory (RAM) devices, or image sensors. Imaging devices may include binoculars, cameras (handheld, still, or video), telescopes, and/or cellphones/smartphones.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A method for making a semiconductor structure, comprising:
forming an intermediate structure in a dielectric layer that comprises a trench connected to a via, the via connecting to an interconnection on a semiconductor substrate;
depositing a first electrically conductive material over the intermediate structure that fills the via; and
depositing a second electrically conductive material to fill the trench of the intermediate structure and obtain the semiconductor structure, wherein a conductive path extending vertically from the interconnection to an upper surface of the semiconductor structure passes through only the first electrically conductive material.

2. The method of claim 1, wherein the via of the intermediate structure is located on a perimeter of a lower surface of the trench.

3. The method of claim 1, wherein a susceptibility to migration of the first electrically conductive material is greater than a susceptibility to migration of the second electrically conductive material.

4. The method of claim 1, wherein the first electrically conductive material is formed from copper, and the second electrically conductive material is AlCu, AlSiCu, Al, or W.

5. The method of claim 1, further comprising forming a barrier layer in the intermediate structure prior to applying the first electrically conductive material.

6. The method of claim 1, wherein the semiconductor structure has the shape of a rectangle, a cross, a parallelogram, or a triangle, when seen in a plan view.

7. The method of claim 5, wherein the semiconductor structure is formed in a peripheral area of a chip area or in a testkey area adjacent a chip area; and
wherein at least one device structure comprising a trench connected to a via is formed concurrently with the intermediate structure, the via of the at least one device structure also connecting an interconnection on the semiconductor substrate;
wherein the barrier layer is concurrently formed in the intermediate structure and the at least one device structure;
wherein the first electrically conductive material is concurrently applied over the intermediate structure and the at least one device structure; and
wherein the second electrically conductive material is concurrently applied over the intermediate structure and the at least one device structure.

8. The method of claim 1, further comprising:
etching a first dielectric layer to form at least one sidewall over a perimeter of the semiconductor structure.

9. A semiconductor system, comprising:
an interconnect layer on a semiconductor substrate having at least one interconnection in a chip area and an interconnection for a semiconductor structure;
at least one device structure in the chip area, comprising a trench and a via connected to the at least one interconnection in the chip area; and
a first semiconductor structure, comprising a trench and a via connected to the interconnection for the semiconductor structure;
wherein the at least one device structure and the first semiconductor structure each further comprise:
a first electrically conductive material filling the via and forming a layer in the trench; and
a second electrically conductive material filling the trench; and
wherein the via of the first semiconductor structure is located on a perimeter of a lower surface of the trench.

10. The semiconductor system of claim 9, wherein a ratio of a surface area of the second electrically conductive material to a surface area of the first electrically conductive material in the at least one device structure is from about 5% to about 20%; and
wherein a ratio of a surface area of the second electrically conductive material to a surface area of the first electrically conductive material in the first semiconductor structure is from about 50% to about 95%.

11. The semiconductor system of claim 9, wherein a ratio of a height of the second electrically conductive material to a height of the first electrically conductive material in the first semiconductor structure is from about 100:150,000 to about 150,000:100.

12. The semiconductor system of claim 9, wherein the at least one device structure and the first semiconductor structure each further comprise a first barrier layer upon surfaces of the via and the trench.

13. The semiconductor system of claim 12, wherein the first barrier layer is formed from TiN, TaN, W, Ti, or Ta.

14. The semiconductor system of claim 9, wherein the at least one device structure further comprises:
a sidewall above and around the filled trench; and
a mirror layer above the filled trench and bounded by the sidewall.

15. The semiconductor system of claim 14, further comprising a second barrier layer upon surfaces of the sidewall and the filled trench.

16. The semiconductor system of claim 14, wherein the at least one device structure further comprises an LED layer above the mirror layer.

17. The semiconductor system of claim 9, wherein the at least one device structure in the chip area is a plurality of device structures, wherein each device structure is electrically isolated from any adjacent device structures.

18. The semiconductor system of claim 9, wherein the first semiconductor structure is in a testkey area that is in a scribe line, or is in a peripheral area of the chip area; or
wherein the first semiconductor structure is in a scribe line, and further comprising a second semiconductor structure in a peripheral area of the chip area.

19. A method for testing an intermediate system, comprising:
receiving the intermediate system, which comprises:
an interconnect layer on a semiconductor substrate having at least one interconnection in a chip area and an interconnection for a testing structure;
at least one device structure in the chip area, comprising a trench and a via connected to the at least one interconnection in the chip area; and
a testing structure, comprising a trench and a via connected to the interconnection for the testing structure;
wherein the at least one device structure and the testing structure each further comprise:
a first barrier layer upon surfaces of the via and the trench;
a first electrically conductive material filling the via and forming a layer in the trench; and
a second electrically conductive material filling the trench; and
wherein the via of the testing structure is located on a perimeter of a lower surface of the trench; and
contacting the testing structure with a probe to conduct testing on the at least one device structure.

20. The method of claim 19, wherein if the at least one device structure passes the testing, then further comprising:
forming a first sidewall above and around the filled trench;
forming a second barrier layer upon surfaces of the first sidewall and the filled trench;
forming a mirror layer above the filled trench and bounded by the first sidewall;
forming a second sidewall above and around the mirror layer; and
forming an LED layer above the mirror layer and bounded by the second sidewall.
